(19) United States
(12) Patent Application Publication
(10) Pub. No.: US 2012/0274358 A1
(43) Pub. Date: Nov. 1, 2012

(54) IDENTICAL-DATA DETERMINATION CIRCUIT

(76) Inventor: Dae-Suk KIM, Gyeonggi-do (KR)

(21) Appl. No.: 13/338,540

(22) Filed: Dec. 28, 2011

(30) Foreign Application Priority Data
Apr. 29, 2011 (KR) 10-2011-0040524

(51) Int. Cl. H03K 5/22

(52) U.S. Cl. 327/64

(57) ABSTRACT

A identical-data determination circuit includes a first activation unit configured to activate an output signal when first and second signals each have a first level, a second activation unit configured to activate the output signal when the first and second signals each have a second level different from the first level, an initialization unit configured to deactivate the output signal when an initialization signal is applied, and a storage unit configured to store the output signal.

### CROSS-REFERENCE TO RELATED APPLICATIONS

The present application claims priority of Korean Patent Application No. 10-2011-0040524, filed on Apr. 29, 2011, which is incorporated herein by reference in its entirety.

### BACKGROUND

1. Field

Exemplary embodiments of the present invention relate to an identical-data determination circuit.

2. Description of the Related Art

An identical-data determination circuit refers to a circuit which determines whether the logic values of input digital signals are identical or not. The identical-data determination circuit may be used as a component of a circuit which performs a desired function inside the integrated circuit. The identical-data determination circuit may be configured in various manners as appropriate according to different design needs and the number of inputs may also differ according to different design needs.

FIG. 1 is a diagram showing an XNOR (exclusive NOR) gate used as an identical-data determination circuit and a truth table of the XNOR gate.

An XNOR gate is a representative identical-data determination circuit capable of determining whether the logic values of input signals are identical or not. The XNOR gate is represented by reference numeral 101 and configured to output an output signal Q with the logic value determined according to the relation between the logic values of input signals A and B.

According to the truth table 102, when the logic values of the two input signals A and B are identical (A=0, B=0 or A=1, B=1), the XNOR gate outputs ‘1’ (high level) as the output signal Q, and when the logic values of the input signals A and B are different from each other (A=0, B=1 or A=1, B=0), the XNOR gate outputs ‘0’ (low level) as the output signal Q.

That is, according to the level of the output signal Q of the XNOR gate, a determination is made as to whether the logic values of the input signals A and B of the XNOR gate are identical or not.

FIG. 2 is a configuration diagram of the XNOR gate. The XNOR gate may be implemented in various manners. At this time, the types and number of logic gates used for implementing the XNOR gate may differ.

A left diagram of FIG. 2 illustrates an example of an XNOR gate configured by using NAND gates. Referring to FIG. 2, the XNOR gate includes a plurality of NAND gates 201 to 205.

A right diagram of FIG. 2 illustrates the configuration of one NAND gate. Referring to FIG. 2, one NAND gate receives two input signals IN1 and IN2 and generates an output signal OUT having the logic value determined according to the logic values of the input signals IN1 and IN2. The relation between the input signals IN1 and IN2 of the NAND gate and the output signal OUT is omitted.

Referring to the right diagram of FIG. 2, one NAND gate includes two PMOS transistors P1 and P2 and two NMOS transistors N1 and N2. Therefore, one XNOR gate may include 10 (2×5) PMOS transistors and 10 (2×5) NMOS transistors.

Meanwhile, an exemplary circuit in which an identical-data determination circuit is a data compression circuit, which compresses data outputted from a bank during a compression test of a memory device. A compression test (or parallel test) is one of test methods for reducing a time during the test of the memory device.

In general, when memory cells of a memory chip are tested one by one in order to determine whether the memory cells have passed or failed, the test time of a semiconductor device becomes longer and the testing costs increase.

Therefore, a compression test is used to reduce the test time. During the compression test, the same data are written into a plurality of cells, and a logic gate such as an XNOR gate is used to read data. When the same data are read from the plurality of cells, a pass determination is indicated by ‘1’ output from the XNOR gate, and when different data is read, a fail determination is indicated by ‘0’ output from the XNOR gate. Through the compression test, the test time may be reduced.

During the compression test, banks are simultaneously enabled to compress output data. Therefore, a data compression circuit has a large number of XNOR gates. Referring to FIG. 2, the conventional XNOR gate includes 20 transistors. Here, when such an XNOR gate is used to implement a data compression circuit, the configuration of the circuit becomes complex, and the area of the circuit increases. According to an example, since the data compression circuit generally uses an XNOR gate having three or more input signals, the data compression circuit includes a larger number of transistors than a XNOR gate having just two input signals.

### SUMMARY

An embodiment of the present invention is directed to an identical-data determination circuit capable of determining whether the logic values of input signals are identical or not, through a simple configuration.

In accordance with an embodiment of the present invention, an identical-data determination circuit includes: a first activation unit configured to activate an output signal when first and second signals each have a first level; a second activation unit configured to activate the output signal when the first and second signals each have a second level different from the first level; an initialization unit configured to deactivate the output signal when an initialization signal is applied; and a storage unit configured to store the output signal.

In accordance with another embodiment of the present invention, an identical-data determination circuit includes: a first activation unit configured to activate an output signal when a plurality of signals have a first level; a second activation unit configured to activate the output signal when the plurality of signals have a second level different from the first level; an initialization unit configured to deactivate the output signal when an initialization signal is applied; and a storage unit configured to store the output signal.

In accordance with yet another embodiment of the present invention, an identical-data determination circuit includes: a first activation unit comprising a plurality of first transistors configured to receive a plurality of signals, respectively, and having a string structure, wherein the first activation unit is configured to activate an output signal when the plurality of signals have a first level; a second activation unit comprising a plurality of second transistors configured to receive the plurality of signals, respectively, and having a string structure, wherein the first activation unit is configured to activate the output signal when the plurality of signals have a second level different from the first level; an initialization unit configured to deactivate the output signal when an initialization signal is applied; and a storage unit configured to store the output signal.

### BRIEF DESCRIPTION OF THE DRAWINGS

FIG. 1 is a diagram showing an XNOR gate used as an identical-data determination circuit and a truth table of the XNOR gate.

FIG. 2 is a configuration diagram of the XNOR gate.

FIG. 3 is a configuration diagram of an identical-data determination circuit in accordance with an embodiment of the present invention.

FIG. 4 is a configuration diagram of an identical-data determination circuit in accordance with another embodiment of the present invention.

FIG. 5 is a configuration diagram of data compression circuits using the identical-data determination circuit in accordance with the embodiment of the present invention.

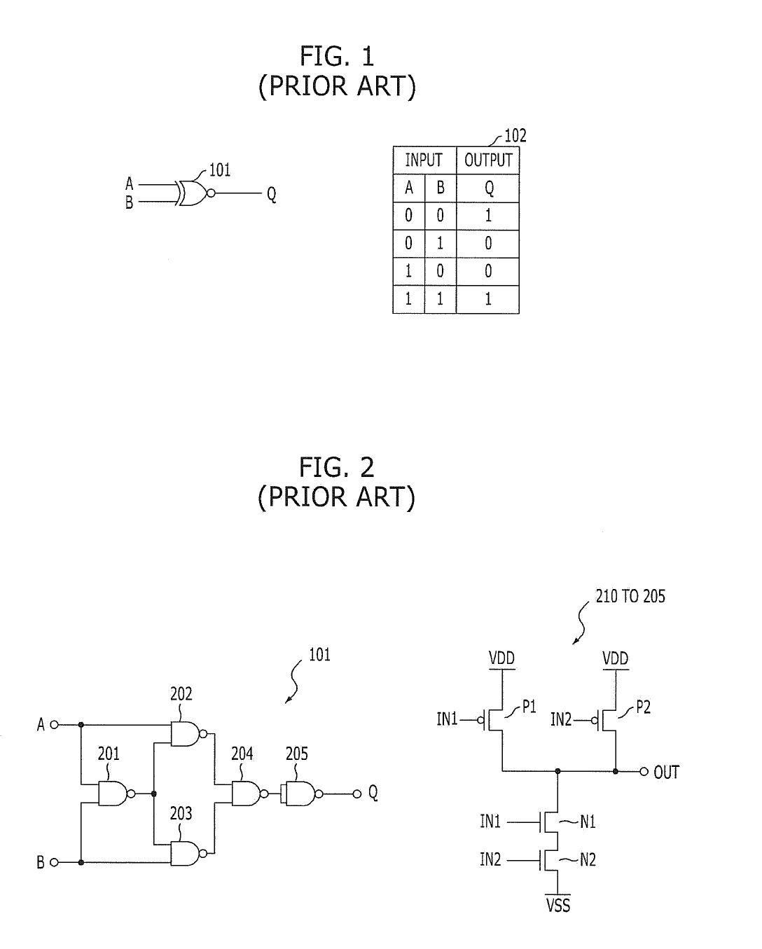

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

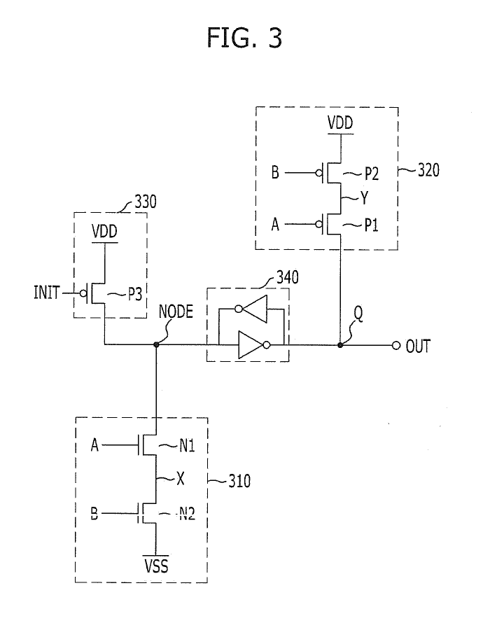

FIG. 3 is a configuration diagram of an identical-data determination circuit in accordance with an embodiment of the present invention.

Referring to FIG. 3, the identical-data determination circuit includes a first activation unit 310, a second activation unit 320, and an initialization unit 330, and a storage unit 340. The first activation unit 310 is configured to activate an output signal Q when first and second signals A and B have a first level. The second activation unit 320 is configured to activate the output signal Q when the first and second signals A and B have a second level. The initialization unit 330 is configured to deactivate the output signal Q when an initialization signal INIT is applied. The storage unit 340 is configured to store the output signal Q.

The activation state of the output signal Q indicates the state of the output signal Q when the two input signals A and B of the identical-data determination circuit have the same logic value. The deactivation state of the output signal Q indicates the state of the output signal Q when the two input signals of the identical-data determination circuit have different logic values or when the identical-data determination circuit is initialized. Depending on the configuration of the identical-data determination circuit, the output signal Q may have a high level or low level when it is activated initially. According to an example, when the logic values of two or more signals are identical, the levels of two or more signals are identical.

FIG. 3 illustrates an identical-data determination circuit in which a first level is a high level and a second level is a low level. In FIG. 3, the output signal Q has a high level in an activation state, and has a low level in a deactivation state.

The identical-data determination circuit is initialized by the initialization unit 330 before determining the identical data of the input signals A and B. When the initialization signal INIT is activated (low level), the output signal Q is deactivated (low level). The initialization unit 330 may include a PMOS transistor P3 having a source configured to receive a power supply voltage VDD, a drain coupled to an internal node NODE, and a gate configured to receive the initialization signal INTI. When the initialization signal INIT is activated, the PMOS transistor P3 is turned on. Then, the voltage of the internal node NODE becomes a high level, and the level of the output signal Q becomes a low level.

The identical-data determination circuit includes the storage unit 340 configured to store the output signal Q. Referring to FIG. 3, the storage unit 340 may include a latch coupled between the internal node NODE and an output node OUT. The output node OUT refers to a node where the output signal is generated.

Since an inverter is coupled to the internal node NODE and the output node OUT, the voltage levels of the internal node NODE and the output node OUT have opposite values. That is, when the voltage level of the internal node NODE is a high level, the voltage level of the output node OUT becomes a low level, and when the voltage level of the internal node NODE is a low level, the voltage level of the output node OUT becomes a high level.

Hereinafter, the operation of the identical-data determination circuit will be described. The following descriptions will be divided into a case where two input signals A and B have the same logic value and a case where two input signals A and B have different logic values.

(1) When the Input Signals A and B have the Same Logic Value

The case where the input signals A and B have the same logic value may include a case in which the levels of the input signals A and B are identical as a high level and a case in which the levels of the input signals A and B are identical as a low level.

First, when the levels of the input signals A and B are identical as a high level, the first activation unit 310 is enabled, and the second activation unit 320 is disabled. The enabled first activation unit 310 has an effect upon the state of the output signal Q, and the disabled second activation unit 320 has no effect upon the state of the output signal Q. The enabled first activation unit 310 activates the output signal Q to a high level.

The first activation unit 310 may include a first NMOS transistor N1 and a second NMOS transistor N2. The first NMOS transistor N1 has a drain coupled to the internal node NODE, a source coupled to a first node X, and a gate configured to receive the first signal A. The second NMOS transistor N2 has a drain coupled to the first node X, a source configured to receive a ground voltage VSS, and a gate configured to receive the second signal B.

The second activation unit 320 may include a first PMOS transistor P1 and a second PMOS transistor P2. The first PMOS transistor P1 has a drain coupled to the output node OUT where the output signal Q is generated, a source coupled to a second node Y, and a gate configured to receive the first signal A. The second PMOS transistor P2 has a drain coupled to the second node Y, a source configured to receive a power supply voltage VDD, and a gate configured to receive the second signal B.

Therefore, when the levels of the input signals A and B are identical as a high level, both of the first and second NMOS transistors included in the first activation unit 310 are turned on to apply the ground voltage VSS to the internal node NODE. The ground voltage VSS is a low-level voltage. Therefore, when the voltage of the internal node NODE becomes a low-level voltage, the voltage of the output node OUT becomes a high-level voltage obtained by inverting the voltage level of the internal node NODE. Accordingly, the output signal Q is activated (that is, having a high level).

Since both of the first and second PMOS transistors P1 and P2 included in the second activation unit 320 are turned off, the first and second PMOS transistors P1 and P2 have no effect upon the voltage of the output node OUT and the level of the output signal Q.

When the levels of the input signals A and B are identical as a low level, the first activation unit 310 is disabled, and the second activation unit 320 is enabled. The enabled second activation unit 320 has an effect upon the state of the output signal Q, and the disabled first activation unit 310 has no effect upon the state of the output signal Q. The enabled second activation unit 320 activates the output signal Q to a high level.

When the levels of the input signals A and B are identical as a low level, both of the first and second PMOS transistors P1 and P2 are turned on to apply the power supply voltage VDD to the output node OUT. Since the power supply voltage VDD is a high-level voltage, the output signal Q is activated.

Since both of the first and second NMOS transistors N1 and N2 included in the first activation unit 310 are turned off, the first and second NMOS transistors N1 and N2 have no effect upon the voltage of the internal node NODE. As a result, the first and second NMOS transistors N1 and N2 have no effect upon the voltage of the output node OUT and the level of the output signal Q.

(2) When the First and Second Signals A and B have Different Logic Levels

When the first signal A has a high level and the second signal B has a low level, or when the first signal A has a low level and the second signal B has a high level, that is, when the first and second signals A and B have different levels, both of the first and second activation units 310 and 320 are disabled, and the output signal Q is maintained in a deactivation state (that is, at a low level).

When the input signals A and B have different logic levels, one of the first and second NMOS transistors N1 and N2 of the first activation unit 310 is necessarily turned off, and one of the first and second PMOS transistors P1 and P2 of the second activation unit 320 is necessarily turned off. Therefore, the ground voltage VSS is not transmitted to the internal node NODE, and the power supply voltage VDD is not transmitted to the output node OUT.

Therefore, the voltage of the output node OUT maintains a voltage (low level) when the output signal Q is initialized. That is, a low level. In other words, the voltage of the output node OUT maintains a state of the output node voltage when the output signal Q is initialized, that is, a deactivation state.

The identical-data determination circuit in accordance with the embodiment of the present invention maintains the output signal Q in an initialization state (deactivation state) using the storage unit 340, and activates the output signal Q, for example, only when the logic values of the input signals A and B are identical. Therefore, the identical-data determination circuit may perform the same operation as the XNOR gate through the simple configuration. The identical-data determination circuit uses nine transistors (five PMOS transistors+four NMOS transistors), which means that the number of transistors is further reduced than in the conventional identical-data determination circuit. Therefore, the area of a circuit in which the identical-data determination circuit is used may be reduced.

The identical-data determination circuit in accordance with the embodiment of the present invention may be configured in such a manner that the first level is set to a low level and the second level is set to a high level. Furthermore, the identical-data determination circuit may be configured in such a manner that the output signal Q has a low level in an activation state and a high level in a deactivation state. In such a case, the initialization unit 330 is configured to initialize the level of the output signal Q to a high level, when the initialization signal INIT is applied, and may include an NMOS transistor. The first activation unit 310 is configured to apply the power supply voltage VDD to the internal node NODE when the logic values of the input signals A and B are a low level and may include two PMOS transistors coupled in series. The second activation unit 320 is configured to apply the ground voltage VSS to the output node OUT when the logic values of the input signals A and B are a high level and may include two NMOS transistors in series. In such a case, the identical-data determination circuit operates in the same manner as an XOR gate.

When the identical-data determination circuit in accordance with the embodiment of the present invention is used as a data compression circuit for a compression test of a memory device, the initialization signal INIT may correspond to a read command, the first signal A may correspond to first data, and the second signal B may correspond to second data. In FIG. 3, a read command is inverted to generate the initialization signal INIT. When a read command RDCMD is applied, the output signal (compressed data) Q of the identical data determination unit is deactivated. Then, when the first and second data are identical, the output signal Q of the identical-data determination circuit may be activated to indicate that the memory device is normal and has passed the test, and when the first and second data are not identical, the output signal Q may maintain a deactivation state to indicate that the memory device is abnormal and did not pass the test.

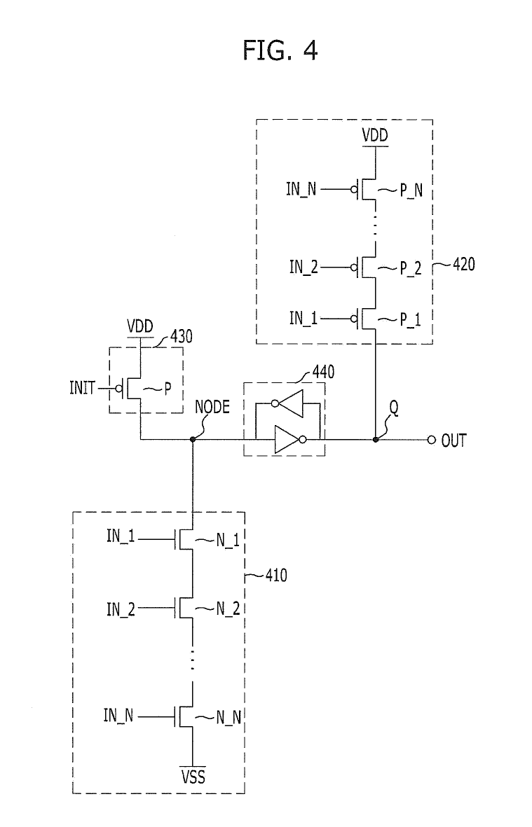

FIG. 4 is a configuration diagram of an identical-data determination circuit in accordance with another embodiment of the present invention.

The identical-data determination circuit of FIG. 4 is an identical-data determination circuit which may be used in a case where an arbitrary number of input signals are used and is used in a more general case than the identical-data determination circuit of FIG. 3.

Referring to FIG. 4, the identical-data determination circuit includes a first activation unit 410, a second activation unit 420, an initialization unit 430, and a storage unit 440. The first activation unit 410 is configured to activate an output signal Q when a plurality of signals IN_1 to IN_N have a first level. The second activation unit 420 is configured to activate the output signal Q when the plurality of signals IN_1 to IN_N have a second level. The initialization unit 430 is configured to deactivate the output signal Q when an initialization signal INIT is applied. The storage unit 440 is configured to store the output signal Q. The plurality of signals IN_1 to IN_N represent input signals of the identical-data determination circuit.

The activation state of the output signal Q indicates the state of the output signal Q when the plurality of signals IN_1 to IN_N have the same logic value. The deactivation state of the output signal Q indicates the state of the output signal Q when the plurality of signals IN_1 to IN_N have different logic values or when the identical-data determination circuit is initialized. Depending on the configuration of the identical-data determination circuit, the output signal Q may have a high level or low level in an activation state. Furthermore, the output signal Q may have a high level or low level in a deactivation state. For illustration purposes, when the logic values of two or more signals are identical, their logic values are assumed to be identical.

FIG. 4 illustrates an identical-data determination circuit in which the first level is set to a high level and the second level is set to a low level. In FIG. 4, the output signal Q has a high level in an activation state and has a low level in a deactivation state.

Since the configurations and operations of the initialization unit 430 and the storage unit 440 are the same as described above with reference to FIG. 3, the detailed descriptions thereof are omitted herein. At this time, the initialization unit 430 may include a PMOS transistor.

Hereinafter, the operation of the identical-data determination circuit will be described. The following descriptions will be divided into a case where the plurality of signals IN_1 to IN_N have the same logic value and a case where any one of the plurality of signals IN_1 to IN_N has a different logic value.

(1) When the Plurality of Signals IN_1 to IN_N have the Same Logic Value

The case where the plurality of signals IN_1 to IN_N have the same logic value include a case in which the logic levels of the signals IN_1 to IN_N are identical as a high level and a case in which the logic levels of the signals IN_1 to IN_N are identical as a low level.

First, when the levels of the signals IN_1 to IN_N are identical as a high level, the first activation unit 410 is enabled, and the second activation unit 420 is disabled. The enabled first activation unit 410 has an effect upon the state of the output signal Q, and the disabled second activation unit 420 has no effect upon the state of the output signal Q. The enabled first activation unit 410 activates the output signal Q to a high level.

Referring to FIG. 4, the first activation unit 410 may include a plurality of NMOS transistors N_1 to N_N coupled in series between an internal node NODE and a ground voltage terminal VSS. Each of the NMOS transistors N_1 to N_N has a gate configured to receive one of the pluralities of signals IN_1 to IN_N.

Referring to FIG. 4, the second activation unit 420 may include a plurality of PMOS transistors P_1 to P_N coupled in series between an output node OUT and a power supply voltage terminal VDD. Each of the PMOS transistors P_1 to P_N has a gate configured to receive one of the signals IN_1 to IN_N.

Therefore, when the levels of the signals IN_1 to IN_N are identical as a high level, all of the NMOS transistors N_1 to N_N included in the first activation unit 410 are turned on to apply a ground voltage VSS to the internal node NODE. The ground voltage VSS is a low-level voltage. Therefore, when the voltage of the internal node NODE becomes a low-level voltage, the voltage of the output node OUT becomes a high-level voltage obtained by inverting the voltage level of the internal node NODE. Accordingly, the output signal Q is activated.

Since all of the PMOS transistors P_1 to P_N included in the second activation unit 320 are turned off, the PMOS transistors P_1 to P_N have no effect upon the voltage of the output node OUT and the level of the output signal Q (that is, at a high level).

When the levels of the signals IN_1 to IN_N are identical as a low level, the first activation unit 410 is disabled, and the second activation unit 420 is enabled. The enabled second activation unit 420 has an effect upon the state of the output signal Q, and the disabled first activation unit 410 has no effect upon the state of the output signal Q. The enabled second activation unit 420 activates the output signal Q to a high level.

When the levels of the signals IN_1 to IN_N are identical as a low level, all of the PMOS transistors P_1 to P_N included in the second activation unit 420 are turned on to apply the power supply voltage VDD to the output node OUT. Since the power supply voltage VDD is a high-level voltage, the output signal Q is activated (that is, at a high level).

Since all of the NMOS transistors N_1 to N_N included in the first activation unit 410 are turned off, the NMOS transistors N_1 to N_N have no effect upon the voltage of the output node OUT and the level of the output signal Q.

(2) When any One of the Plurality of Signals IN_1 to IN_N has a Different Logic Value

When any one of the signals IN_1 to IN_N has a different logic value, both of the first and second activation units 410 and 420 are disabled, and the output signal Q is maintained in a deactivation state.

When any one of the signals IN_1 to IN_N has a different logic value, one or more of the NMOS transistors N_1 to N_N of the first activation unit 410 are turned off, and one or more of the PMOS transistors P_1 to P_N of the second activation unit 420 are turned off. Therefore, the ground voltage VSS is not transmitted to the internal node NODE, and the power supply voltage VDD is not transmitted to the output node OUT.

Therefore, the voltage of the output node OUT maintains a voltage of the state when the identical-data determination circuit is initialized, that is, a low level. Here, the voltage of the output node OUT maintains a state when the output signal Q is initialized, that is, a deactivation state.

The identical-data determination circuit of FIG. 4 has all of the same features of the identical-data determination circuit of FIG. 3. The effect of reducing the area of the circuit increases as the number of input signals of the identical-data determination circuit increases. That is because, whenever the number of input signals of the identical-data determination circuit increases by one, the number of transistors increases, for example, only by two (one NMOS transistor for the first activation unit 410 and one PMOS transistor for the second activation unit 420). The identical-data determination circuit in accordance with the embodiment of the present invention may be configured in such a manner that the first level is set to a low level and the second level is set to a high level. Furthermore, the identical-data determination circuit may be configured in such a manner that the output signal Q has a low level in an activation state and a high level in a deactivation state. In such a case, the initialization unit 430 is configured to initialize the level of the output signal Q to a high level, when the initialization signal INIT is applied and may include an NMOS transistor. The first activation unit 410 is configured to apply the power supply voltage VDD to the internal node NODE when all of the logic values of the signals IN_1 to IN_N are a low level and may include a plurality of PMOS transistors coupled in series. The second activation unit 420 is configured to apply the ground voltage VSS to the output node OUT when all of the logic values of the signals IN_1 to IN_N are a high level and may include a plurality of NMOS transistors coupled in series. In such a case, the identical-data determination circuit operates in the same manner as an XOR gate having a plurality of input signals.

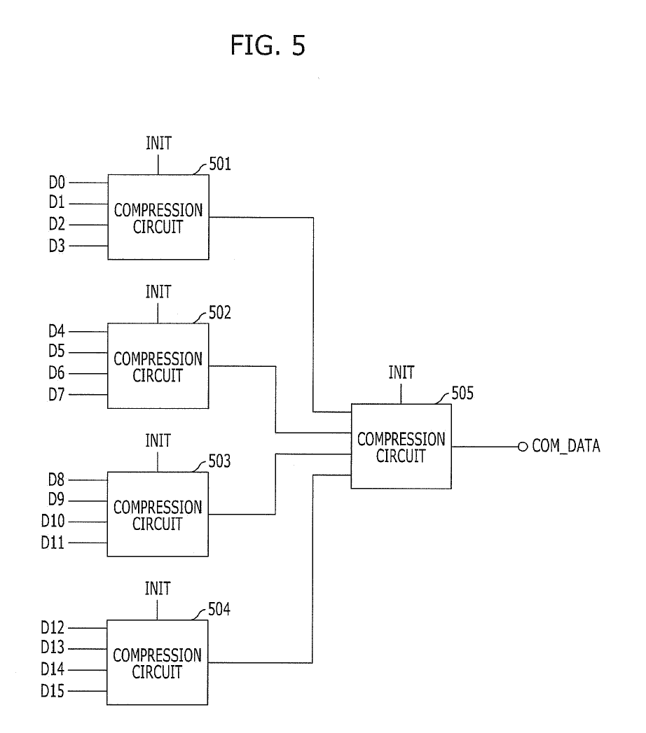

FIG. 5 is a configuration diagram of data compression circuits using the identical-data determination circuit in accordance with the embodiment of the present invention. The data compression circuits of FIG. 5 are used during a compression test of a memory device.

Each of the compression circuits 501 to 505 of FIG. 5 has the same configuration as that of the identical-data determination circuit of FIG. 4 and may include four signals. An initialization signal INIT may correspond to a read command, and a plurality of signals IN_1 to IN_N of the compression circuits 501 to 505 may correspond to different ones of data D0 to D15, respectively.

The four compression circuits 501 to 504 at a first stage are configured to activate an output, when the data D0 to D3, D4 to D7, D8 to D11, and D12 to 15 inputted to the compression circuits 501 to 504, respectively, are identical. The compression circuit 505 at a second stage is configured to activate the value of compressed data COM_DATA, when the outputs of the compression circuits 501 to 504 at the first stage are activated. When the identical-data determination circuit of FIG. 4 is used, the value of the compressed data COM_DATA is activated to a high level. That is, 16 data D0 to D15 are processed into one compressed data COM_DATA.

During the compression test, a determination is made as to whether a memory device has passed or not according to the logic value of the compressed data COM_DATA.

Referring to FIG. 4, the identical-data determination circuit in accordance with the embodiment of the present invention will be described.

As illustrated in FIG. 4, the identical-data determination circuit in accordance with the embodiment of the present invention includes a plurality of first transistors N_1 to N_N having a string structure and configured to receive corresponding signals among the plurality of signals IN_1 to IN_N, the first activation unit 410 configured to activate the output signal Q when all of the signals IN_1 to IN_N have the first level, a plurality of second transistors P_1 to P_N having a string structure and configured to receive corresponding signals among the plurality of signals IN_1 to IN_N, the second activation unit 420 configured to activate the output signal Q when all of the signals IN_1 to IN_N have the second level, the initialization unit 430 configured to deactivate the output signal Q when the initialization signal INIT is applied, and the storage unit 440 configured to store the output signal Q.

Since the operation of the identical-data determination circuit is performed in the same manner as described with reference to FIG. 4, the descriptions thereof are omitted herein. When the first level is a high level and the second level is a low level, the plurality of first transistors N_1 to N_N may include NMOS transistors, and the plurality of second transistors P_1 to P_N may include PMOS transistors.

The identical-data determination circuit in accordance with the embodiment of the present invention activates the output signal Q using the plurality of transistors N_1 to N_N and P_1 to P_N forming a string structure. The identical-data determination circuit has at least the same features described with reference to FIGS. 3 and 4.

In accordance with the embodiment of the present invention, the identical-data determination circuit may determine whether the logic values of input signals are identical or not, through a simple configuration, thereby reducing an occupied area.

While the present invention has been described with respect to the specific embodiments, it will be apparent to those skilled in the art that various changes and modifications may be made without departing from the spirit and scope of the invention as defined in the following claims.

What is claimed is:

1. An identical-data determination circuit comprising:
a first activation unit configured to activate an output signal when first and second signals each have a first level;
a second activation unit configured to activate the output signal when the first and second signals each have a second level different from the first level;
an initialization unit configured to deactivate the output signal when an initialization signal is applied; and
a storage unit configured to store the output signal.

2. The identical-data determination circuit of claim 1, wherein, when the first and second signals have different levels, the first and second activation units are configured to be disabled, so that the output signal is maintained in a deactivation state.

3. The identical-data determination circuit of claim 1, wherein the first level is a high level and the second level is a low level.

4. The identical-data determination circuit of claim 1, wherein the initialization unit comprises a PMOS transistor having a source configured to receive a power supply voltage, a drain coupled to an internal node, and a gate configured to receive the initialization signal.

5. The identical-data determination circuit of claim 1, wherein the first activation unit comprises:
a first NMOS transistor having a drain coupled to an internal node, a source coupled to a first node, and a gate configured to receive the first signal; and
a second NMOS transistor having a drain coupled to a first node, a source configured to receive a ground voltage, and a gate configured to receive the second signal.

6. The identical-data determination circuit of claim 5, wherein the second activation unit comprises:
a first PMOS transistor having a drain coupled to an output node where the output signal is generated, a source coupled to a second node, and a gate configured to receive the first signal; and
a second PMOS transistor having a drain coupled to a second node, a source configured to receive a power supply voltage, and a gate configured to receive the second signal.

7. The identical-data determination circuit of claim 6, wherein the internal node and the output node have opposite voltage levels due to the storage unit coupled between the internal node and the output node.

8. The identical-data determination circuit of claim 5, wherein the first level is a low level and the second level is a high level.

9. The identical-data determination circuit of claim 1, wherein, when the identical-data determination circuit is used as a data compression circuit for a compression test of a memory device, the initialization signal corresponds to a read command, the first signal corresponds to first data, and the second signal corresponds to second data.

10. An identical-data determination circuit comprising:
a first activation unit configured to activate an output signal when a plurality of signals have a first level;
a second activation unit configured to activate the output signal when the plurality of signals have a second level different from the first level;
an initialization unit configured to deactivate the output signal when an initialization signal is applied; and
a storage unit configured to store the output signal.

11. The identical-data determination circuit of claim 10, wherein, when one or more of the plurality of signals have different levels, both of the first and second activation units are configured to be deactivated, so that the output signal is maintained in a deactivation state.

12. The identical-data determination circuit of claim 10, wherein the first level is a high level and the second level is a low level.

13. The identical-data determination circuit of claim 10, wherein, when the identical-data determination circuit is used as a data compression circuit for a compressed data of a memory device, the initialization signal corresponds to a read command, and the plurality of signals represent different ones of data.

14. An identical-data determination circuit comprising:
a first activation unit comprising a plurality of first transistors configured to receive a plurality of signals, respectively, and having a string structure, wherein the first activation unit is configured to activate an output signal when the plurality of signals have a first level;
a second activation unit comprising a plurality of second transistors configured to receive the plurality of signals, respectively, and having a string structure, wherein the first activation unit is configured to activate the output signal when the plurality of signals have a second level different from the first level;
an initialization unit configured to deactivate the output signal when an initialization signal is applied; and
a storage unit configured to store the output signal.

15. The identical-data determination circuit of claim 14, wherein, when one or more of the plurality of signals have different levels, both of the first and second activation units are configured to be deactivated so that the output signal is maintained in a deactivation state.

16. The identical-data determination circuit of claim 14, wherein the plurality of first transistors comprise NMOS transistors and the plurality of second transistors comprise PMOS transistors.
